(19) United States
(12) Patent Application Publication
(10) Pub. No.: US 2021/0043842 A1
(43) Pub. Date: Feb. 11, 2021

(54) ELECTRODE INTERFACE LAYER MATERIAL, ZWITTERIONIC POLYMER AND ORGANIC PHOTOVOLTAIC DEVICE

(71) Applicant: WAYS TECHNICAL CORP., LTD., Taoyuan City (TW)

(72) Inventors: Hung-Min SHIH, Taoyuan City (TW); I-CHENG PAN, Taoyuan City (TW); Hsin-Feng CHANG, Taoyuan City (TW); Chung-Wen KO, Taoyuan City (TW)

(21) Appl. No.: 16/930,968

(22) Filed: Jul. 16, 2020

(30) Foreign Application Priority Data
Aug. 8, 2019 (TW) 108128241

(51) Int. Cl. H01L 51/00; H01L 31/0224

(52) U.S. Cl. CPC H01L 51/0034; H01L 51/5056; H01L 31/022425

(57) ABSTRACT

An electrode interface layer material is generated by using a modifier to react with polyethyleneimine, and the amine group on the polyethyleneimine is converted into an ammonium group by reacting with the modifier to form a zwitterionic polyethyleneimine. When an active layer containing a non-fullerene material is formed on the surface of the electrode interface layer, or when the surface of the electrode interface layer is contacted with a non-fullerene material, the possibility that the non-fullerene material is destroyed by the amine groups in the electrode interface layer can be reduced. In addition, the aforementioned electrode interface layer material or zwitterionic polymer is used for an organic photovoltaic device.

### BACKGROUND

### Technical Field

The present invention relates to an electrode interface layer material, a zwitterionic polymer and applications thereof in organic photovoltaic devices.

### Description of Related Art

Organic solar cells have the advantages of light weight, simple manufacturing process, low manufacturing cost, portability and large-area process, and the photovoltaic characteristics of organic solar cells can be optimized through structural design of device. Therefore, organic solar cells are widely studied, and their applicability and prospect are very broad.

Organic solar cells have been widely developed, in which N-type inorganic oxide electrode interface layer material, such as titanium oxide (TiO₂) and zinc oxide (ZnO), is used as an electrode material with modified interface for making an electrode interface layer (such as a hole-blocking layer). The N-type inorganic oxide electrode interface layer material is modified to facilitate charge transfer and also to match the work function of the electrode with the energy level of an active layer. However, oxide material such as titanium oxide or zinc oxide requires a high-temperature process (greater than 150° C.) it is extremely inconvenient when the oxide material is used in a flexible substrate to make the organic solar cell due to the temperature restriction.

### SUMMARY

Therefore, the present invention provides an electrode interface layer material suitable for a low-temperature manufacturing process. The electrode interface layer material is used to make an electrode interface layer. The present invention utilizes lone electron pairs on the nitrogen of the amine groups on the main chain and side chain of polyethyleneimine [linear polyethyleneimine (PEI) or branched polyethyleneimine (PEI)] to react with a modifier to form an electrode interface layer material with a zwitterionic polyethyleneimine, so that the nitrogen of the amine groups on the main chain and side chain of the zwitterionic polyethyleneimine have no lone electron pair or only exist small number of lone electron pairs, or the number of lone electron pairs on the nitrogen of the amine groups on the main chain and side chain of the zwitterionic polyethyleneimine are less than the number of lone electron pairs on the nitrogen of the amine groups on the main chain and side chain of polyethyleneimine. In other words, in the present invention, the amine group on the polyethyleneimine is converted into an ammonium group by reacting with the modifier. When an active layer (ATL) containing a non-fullerene material is formed on the surface of the electrode interface layer, or when the surface of the electrode interface layer is contacted with a non-fullerene material, the nitrogen of the amine groups on the main chain and side chain of the zwitterionic polyethyleneimine have no lone electron pair or only exist small number of lone electron pairs, or the number of lone electron pairs on the nitrogen of the amine groups on the main chain and side chain of the zwitterionic polyethyleneimine are less than the number of lone electron pairs on the nitrogen of the amine groups on the main chain and side chain of polyethyleneimine. Therefore, the possibility of damage to the non-fullerene material can be reduced. Furthermore, since the zwitterionic polyethyleneimine is soluble in water and alcoholic solvent (such as n-butanol, boiling point at about 117.7° C.), it can be used in a low-temperature (such as less than 150° C.) process, and is suitable for a coating process or a large-area process to obtain a film with better flatness and uniformity. The zwitterionic polyethyleneimine can be further applied to a roll-to-roll process, so an organic photovoltaic device having the advantages such as plasticity and light weight can be produced at low cost.

The present invention provides an electrode interface layer material comprising polyethyleneimine having a zwitterionic group, the zwitterionic group having a cationic group and an anionic group. The cationic group is selected from the group consisting of a secondary ammonium cation group, a tertiary ammonium cation group and a quaternary ammonium cation group.

According to the aforementioned electrode interface layer material, the anionic group of the zwitterionic group is selected from the group consisting of an oxyanion group, a carboxylate anion group, a phosphate anion group and a sulfonate anion group.

According to the aforementioned electrode interface layer material, the polyethyleneimine having the zwitterionic group is formed by a reaction of polyethyleneimine and a modifier.

According to the aforementioned electrode interface layer material, the modifier is epoxide, acid anhydride, lactone, sultone or phosphate. The polyethyleneimine having the zwitterionic group is formed by the reaction of polyethyleneimine with epoxide, acid anhydride, lactone, sultone or phosphate. The epoxide can be ethylene oxide.

According to the aforementioned electrode interface layer material, the polyethyleneimine having the zwitterionic group is formed by a crosslinking reaction of polyethyleneimine and a compound having at least two crosslinking groups.

According to the aforementioned electrode interface layer material, the crosslinking group is an ethylene oxide group, an acid anhydride group or an isocyanate group.

According to the aforementioned electrode interface layer material, the polyethyleneimine having the zwitterionic group is formed by the following steps: polyethyleneimine undergoes a crosslinking reaction with a compound having at least two crosslinking groups; then, the crosslinked polyethyleneimine reacts with a modifier. The modifier is lactone, sultone or phosphate.

According to the aforementioned electrode interface layer material, the anionic group of the zwitterionic group is the oxyanion group, and polyethyleneimine is crosslinked with an epoxide which is used as a cross-linker, the epoxide is glycerol diglycidyl ether, bisphenol A diglycidyl ether, 1,4-butanediol diglycidyl ether, poly(propylene glycol) diglycidyl ether, polyoxypropylene diglycidyl ether or trimethylolpropane triglycidyl ether.

According to the aforementioned electrode interface layer material, the anionic group of the zwitterionic group is the carboxylate anion group, polyethyleneimine is crosslinked with acid anhydride which is used as a cross-linker, and the acid anhydride is acetic anhydride or maleic anhydride.

According to the aforementioned electrode interface layer material, the anionic group of the zwitterionic group is the sulfonate anion group, polyethyleneimine is crosslinked with sultone which is used as a cross-linker, and the sultone is 1,3-propanesultone or 1,4-butanesultone.

According to the aforementioned electrode interface layer material, a solvent is included for the polyethyleneimine having the zwitterionic group. The solvent is alcohol.

According to the aforementioned electrode interface layer material, another solvent for the polyethyleneimine having the zwitterionic group is included. The solvent can be a mixture of alcohol and water.

According to the aforementioned electrode interface layer material, the polyethyleneimine having the zwitterionic group is dissolved as an aqueous solution. The pH value of the aqueous solution is adjusted with acetic acid, sulfuric acid, hydrochloric acid, phosphoric acid, perchloric acid, carbonic acid, nitric acid, p-toluenesulfonic acid or trifluoroacetic acid.

According to the aforementioned electrode interface layer material, the pH value of the aqueous solution of the polyethyleneimine having the zwitterionic group is between 5-8.

According to the aforementioned electrode interface layer material, the electrode interface layer material is suitable for making an electrode interface layer of an inverted organic solar cell; the surface of the electrode interface layer includes an active layer containing a non-fullerene material, or the surface of the electrode interface layer is contacted with the non-fullerene material.

The present invention also provides an organic photovoltaic device including the aforementioned electrode interface layer material.

According to the aforementioned organic photovoltaic device, the organic photovoltaic device includes: a first electrode; an electrode interface layer deposited on the first electrode; an active layer deposited on the electrode interface layer; a hole-transporting layer deposited on the active layer; and a second electrode deposited on the hole-transporting layer. The electrode interface layer contains the electrode interface layer material.

According to the aforementioned organic photovoltaic device, the organic photovoltaic device includes: a first electrode; a hole-transporting layer deposited on the first electrode; an active layer deposited on the hole-transporting layer; an electrode interface layer deposited on the active layer; and a second electrode deposited on the electrode interface layer. The electrode interface layer contains the electrode interface layer material.

The present invention also provides a zwitterionic polymer, represented by the following formula (1):

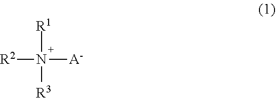

wherein,

N is nitrogen and N⁺ is a cationic group;

R¹, R² and R³ are independently H or a polyethyleneimine group, and at least one of R¹, R² and R³ is the polyethyleneimine group; and

A⁻ is an anionic group, and A⁻ is a substituted alkyl group having 1 to 4 carbons in which one H in the chain is substituted with an oxyanion group (—O⁻), a carboxylate anion group (—C(═O)O⁻), a phosphate anion group (—PO₄³⁻) or a sulfonate anion group (—S(═O)(═O)—O⁻).

According to the aforementioned zwitterionic polymer, the zwitterionic polymer is suitable for making an electrode interface layer of an inverted organic solar cell; the surface of the electrode interface layer includes an active layer containing a non-fullerene material, or the surface of the electrode interface layer is contacted with the non-fullerene material.

The present invention also provides an organic photovoltaic device including the aforementioned zwitterionic polymer.

According to the aforementioned organic photovoltaic device, the organic photovoltaic device includes: a first electrode; an electrode interface layer deposited on the first electrode; an active layer deposited on the electrode interface layer; a hole-transporting layer deposited on the active layer; and a second electrode deposited on the hole-transporting layer. The electrode interface layer contains the zwitterionic polymer.

According to the aforementioned organic photovoltaic device, the organic photovoltaic device includes: a first electrode; a hole-transporting layer deposited on the first electrode; an active layer deposited on the hole-transporting layer; an electrode interface layer deposited on the active layer; and a second electrode deposited on the electrode interface layer. The electrode interface layer contains the zwitterionic polymer.

### BRIEF DESCRIPTION OF THE DRAWINGS

FIG. 1 is a schematic diagram of an organic photovoltaic device in accordance with the first embodiment of the present disclosure.

FIG. 2 is a schematic diagram of the organic photovoltaic device in accordance with the second embodiment of the present disclosure.

FIG. 3 is a graph showing voltage-current density of the organic photovoltaic devices of Examples 5 to 8 and Comparative Example 1 of the present disclosure.

FIG. 4 is a graph showing voltage-current density of the organic photovoltaic devices of Examples 9 to 10 and Comparative Example 2 of the present disclosure.

FIG. 5 is a graph showing voltage-current density of the organic photovoltaic devices of Example 11 and Comparative Example 3 of the present disclosure.

### DESCRIPTION OF THE EXEMPLARY EMBODIMENTS

Hereinafter, the present invention will be described in detail through preferred embodiments, so that a person ordinarily skilled in the art can easily understand the benefits and effects disclosed in the description of the present invention. However, the embodiments are examples, and the present invention is not limited thereto.

The present invention provides an electrode interface layer material, which is suitable for making an electrode interface layer of an inverted organic solar cell. The surface of the electrode interface layer includes an active layer containing a non-fullerene material, or the surface of the electrode interface layer is contacted with a non-fullerene material.

The electrode interface layer material comprises polyethyleneimine having a zwitterionic group, and the zwitterionic group has a cationic group and an anionic group. The cationic group is selected from the group consisting of a secondary ammonium cation group, a tertiary ammonium cation group and a quaternary ammonium cation group. The anionic group of the zwitterionic group is selected from the group consisting of an oxyanion group, a carboxylate anion group, a phosphate anion group and a sulfonate anion group.

Alternatively, the electrode interface layer material comprises a polymer with the following formula (1). The polyethyleneimine having the zwitterionic group may be the polymer with the following formula (1):

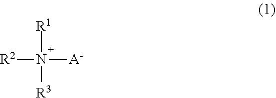

In the polymer with the above formula (1), N is nitrogen and N⁺ is a cationic group.

In the formula (1), R¹, R² and R³ are independently H or a polyethyleneimine group, and at least one of R¹, R² and R³ is the polyethyleneimine group. When two of R¹, R² and R³ are H and the other is a polyethyleneimine group, N⁺ is a cationic group of a secondary ammonium cationic group; when only one of R¹, R² and R³ is H and the other two are polyethyleneimine groups, N⁺ is a cationic group of tertiary ammonium cationic group; when R¹, R² and R³ are all polyethyleneimine groups, N⁺ is a cationic group of tertiary ammonium cationic group.

In the formula (1), A⁻ is an anionic group, and A⁻ is a substituted alkyl group having 1 to 4 carbons in which one H in the chain is substituted with an oxyanion group (—O⁻), a carboxylate anion group (—C(═O)O⁻), a phosphate anion group(—PO₄³⁻) or a sulfonate anion group (—S(═O)(═O)—O⁻).

In the formula (1), the mole number of the cationic group is equal to the mole number of the anionic group, or the number of the cationic group is equal to the number of the anionic group.

The polyethyleneimine having the zwitterionic group can be prepared in three ways. In preparation method (A), the polyethyleneimine having the zwitterionic group is formed by a reaction of polyethyleneimine and a modifier, and the modifier is epoxide, acid anhydride, lactone, sultone or phosphate. In preparation method (B), the polyethyleneimine having the zwitterionic group is formed by a crosslinking reaction of polyethyleneimine and a compound having at least two crosslinking groups. In preparation method (C), the polyethyleneimine having the zwitterionic group is formed by the following steps: polyethyleneimine undergoes a crosslinking reaction with a compound having at least two crosslinking groups; then, the crosslinked polyethyleneimine reacts with a modifier, the modifier is lactone, sultone or phosphate.

For ease of explanation and understanding, the following is an example of preparation method (A) as an embodiment.

The aforementioned electrode interface layer material or the zwitterionic polymer of the formula (1) is prepared according to one of the following methods for manufacturing electrode interface layer material (also referred to as methods for manufacturing zwitterionic polymer). The method for manufacturing electrode interface layer material (or the method for manufacturing zwitterionic polymer) may be one of the following Method 1 and Method 2.

Method 1: (1) Prepare polyethyleneimine and the modifier according to the weight corresponding to polyethyleneimine and the modifier. The polyethyleneimine can be branched polyethyleneimine (b-PEI). The branched polyethyleneimine is composed of primary, secondary and tertiary amines with a 33%:41%:26% amine group ratio. For example, the branched polyethyleneimine could be a molecular with a weight average molecular weight of about 25000 g/mol. (Sigma-Aldrich, Product Number: 408727, CAS Number: 9002-98-6). (2) Place the prepared polyethyleneimine and the modifier in a reaction bottle, and then add 20 ml 2-butanol to stir until dissolved. It is continuously heated at 80° C. for 12 to 16 hours under nitrogen system. Method 1 is applicable to Example 1, Example 2 and Example 3.

Method 2: (1) Prepare polyethyleneimine, a first modifier and a second modifier according to the weight corresponding to polyethyleneimine, the first modifier and the second modifier(same as the Method 1). (2) Place the prepared polyethyleneimine and the first modifier in a reaction bottle, and then add 20 ml 2-butanol to stir until dissolved and continue heating at 80° C. for 12 to 16 hours under a nitrogen system. The temperature is lowered to room temperature after heating. (3) Then, the second modifier is added in the reaction bottle, which is continuously heated at 70° C. for 16 hours. Method 2 is applicable to Example 4.

The following describes the properties and effects of the present invention in detail through examples. This embodiment is only for illustrating the nature of the present invention, and the present invention is not limited to those exemplified in this embodiment.

Example 1 is to prepare Polymer 1 of the zwitterionic polymer (polyethyleneimine having zwitterionic group) according to the aforementioned Method 1, wherein the anionic group of the zwitterionic polymer is a substituted alkyl group having 2 carbons in which one H in the chain is substituted with an oxyanion group (—O⁻). In Example 1, the modifier is glycerol diglycidyl ether, the weight of polyethyleneimine is 1.0 g and the weight of glycerol diglycidyl ether is 0.5 g. In particular, Polymer 1 can be cross-linked with glycerol diglycidyl ether which is used as a cross-linker. Therefore, the anionic group of the zwitterionic group is an oxyanion group, and polyethyleneimine is crosslinked with ethylene oxide which is used as a cross-linker, and ethylene oxide is glycerol diglycidyl ether, bisphenol A diglycidyl ether, 1,4-butanediol diglycidyl ether, poly(propylene glycol) diglycidyl ether, polyoxypropylene diglycidyl ether or trimethylolpropane triglycidyl ether.

Example 2 is to prepare Polymer 2 of the zwitterionic polymer (polyethyleneimine having zwitterionic group) according to the aforementioned Method 1, wherein the anionic group of the zwitterionic polymer is a substituted alkyl group having 3 carbons in which one H in the chain is substituted with a carboxylate anion group (—C(═O)O⁻). In Example 2, the modifier is glutaric anhydride, the weight of polyethyleneimine is 1.0 g and the weight of glutaric anhydride is 0.5 g. Of course, similarly, Polymer 2 can be crosslinked with acid anhydride which is used as a cross-linker, and the anionic group of the zwitterionic group is a carboxylate anion group, and polyethyleneimine can be crosslinked with acid anhydride which is used as a cross-linker, and acid anhydride is acetic anhydride or maleic anhydride.

Example 3 is to prepare Polymer 3 of the zwitterionic polymer (polyethyleneimine having zwitterionic group) according to the aforementioned Method 1, wherein the anionic group of the zwitterionic polymer is a substituted alkyl group having 4 carbons in which one H in the chain is substituted with a sulfonate anion group (—S(═O)(═O)—O⁻). In Example 3, the modifier is 1,4-butanesultone, the weight of polyethyleneimine is 1.0 g and the weight of 1,4-butanesultone is 0.5 g. Of course, similarly, Polymer 3 can be crosslinked with sultone which is used as a cross-linker, and the anionic group of the zwitterionic group is a sulfonate anion group, and the polyethyleneimine can be crosslinked with sultone which is used as a cross-linker, and sultone is 1,3-propanesultone or 1,4-butanesultone.

Example 4 is to prepare Polymer 4 of the zwitterionic polymer (polyethyleneimine having zwitterionic group) according to the aforementioned Method 2, wherein the anionic group of the zwitterionic polymer has a substituted alkyl group having 2 carbons in which one H in the chain is substituted with an oxyanion group (—O⁻) and a substituted alkyl group having 4 carbons in which one H in the chain is substituted with a sulfonate anion (—S(═O)(═O)—O⁻) group. In Example 4, the first modifier is glycerol diglycidyl ether and the second modifier is 1,4-butanesultone. The weight of polyethyleneimine is 1.0 g, the weight of glycerol diglycidyl ether is 0.25 g and the weight of 1,4-butanesultone is 0.25 g.

The following description uses the zwitterionic polymer (polyethyleneimine having zwitterionic group) of the present invention to produce an organic photovoltaic device.

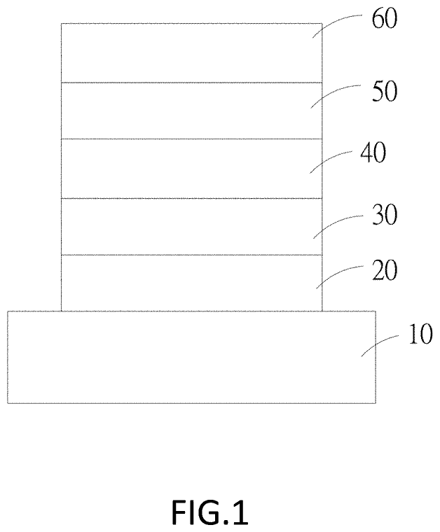

FIG. 1 is a schematic diagram of an organic photovoltaic device in accordance with the first embodiment of the present invention. The organic photovoltaic device includes: a first electrode (20); an electrode interface layer (30) deposited on the first electrode (20); an active layer (40) deposited on the electrode interface layer (30); a hole-transporting layer (50) deposited on the active layer (40); and a second electrode (60) deposited on the hole-transporting layer (50). In addition, the organic photovoltaic device may further include a substrate (10), and the first electrode (20) is deposited on the substrate (10).

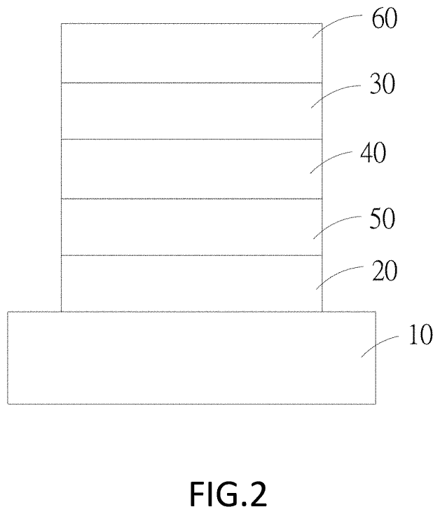

The present invention provides the second embodiment of the organic photovoltaic device as shown in FIG. 2. The organic photovoltaic device includes: a first electrode (20); a hole-transporting layer (50) deposited on the first electrode (20); an active layer (40) deposited on the hole-transporting layer (50); an electrode interface layer (30) deposited on the active layer (40); and a second electrode (60) deposited on the electrode interface layer (30). In addition, the organic photovoltaic device may further include a substrate (10), and the first electrode (20) is deposited on the substrate (10).

For the convenience of description and understanding, the following is the structure of the first embodiment of the organic photovoltaic device shown in FIG. 1.

The substrate (10) is preferably a glass substrate or a transparent resin film having mechanical strength, thermal strength and transparency. Examples of the material of the transparent resin film include polyethylene, ethylene-vinyl acetate copolymer, ethylene-vinyl alcohol copolymer, polypropylene, polystyrene, poly(methyl methacrylate), polyvinyl chloride, polyvinyl alcohol, polyvinyl butyral, nylon, polyether ether ketone, polysulfone, polyether sulfone, tetrafluoroethylene-perfluoroalkyl vinyl ether copolymer, polyvinyl fluoride, tetrafluoroethylene-ethylene copolymer, tetrafluoroethylene-hexafluoropropylene copolymer, polychlorotrifluoroethylene, polyvinylidene difluoride, polyester, polycarbonate, polyurethane, polyimide, polyetherimide, etc. Preferably, the substrate (10) is a glass substrate.

In addition to metal such as gold, platinum, chromium, nickel, etc., the material of the first electrode (20) preferably is transparent metal oxide of indium and tin, or a composite metal oxide (indium tin oxide (ITO), indium zinc oxide (IZO), etc.]. Preferably, the material of the first electrode (20) is indium tin oxide.

Referring to Table 1, the material of the electrode interface layer (30) of Comparative Example 1, Comparative Example 2 and Comparative Example 3 is ZnO (zinc oxide), and the materials of the electrode interface layer (30) of Examples 5 to 11 are respectively Polymer 1 (in Example 1), Polymer 2 (in Example 2), Polymer 3 (in Example 3) and Polymer 4 (in Example 4).

The active layer (40) is a bulk heterojunction (BHJ) composed of an electron donor and an electron acceptor. The active layer (40) is non-fullerence material. The active layer (40) is obtained by mixing the electron donor and the non-fullerene acceptor (NFA) according to the weight ratio listed in Table 1 described later. The electron donor is selected from Electron Donor 1 and Electron Donor 2 described later. The electron acceptor is selected from Electron Acceptor 1, Electron Acceptor 2 and Electron Acceptor 3 described later.

Wherein, Electron Donor 1 is PBDB-T (poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-e]dithiophene-4,8-dione)]), and Electron Acceptor 1 is ITIC (3,9-bis(2-methylene-(3-(1,1-dicyanomethylene)-indanone))-5,5,11,11-tetrakis(4-hexylphenyl)-dithieno[2,3-d:2′,3-d′]-s-indaceno[1,2-b:5,6 -b′]dithiophene. The following are the structures of Electron Donor 1 (PBDB-T) and Electron Acceptor 1 (ITIC).

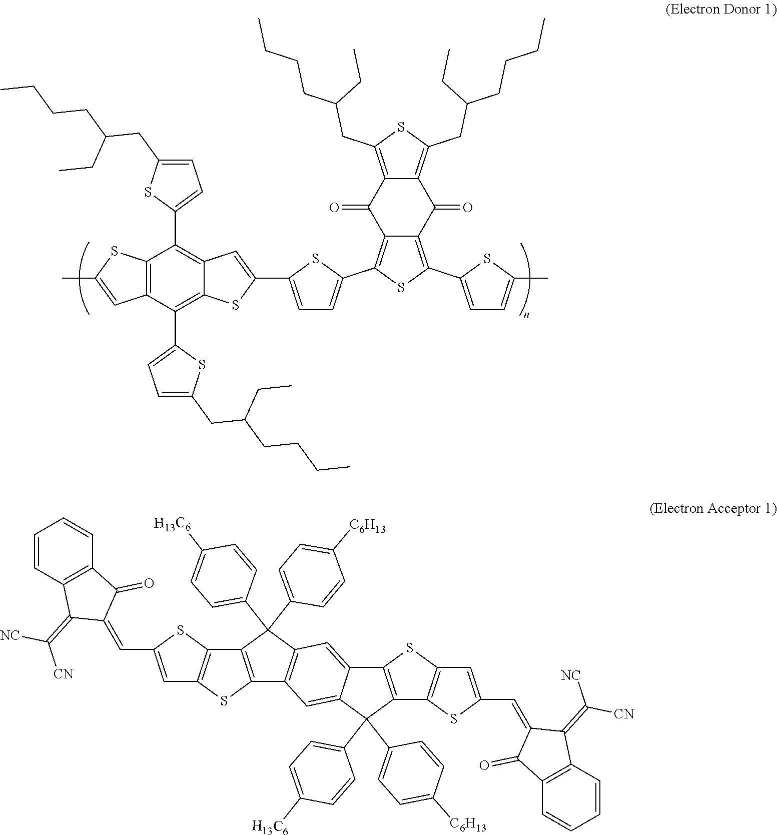

Electron Donor 2 is (poly(4,8-bis(5-(2-ethylhexyl)-4-chlorothiophen-2-yl)-benzo[1,2-b:4,5-b′]dithiophene))-bisdecyl-2,2′:5′,2″-terthiophene-3,3″-dicarboxylate), and Electron Acceptor 2 is (4,8-bis(5-(2-ethylhexyl)thiophen-2-yl)benzo[1,2-b:4,5 -b′]di(cyclopenta-dithiophene)bis-(2-(3-oxo-2,3-dihydroinden-5,6-dichloro-1-ylidene)-malononitrile. The following are the structures of Electron Donor 2 and Electron Acceptor 2.

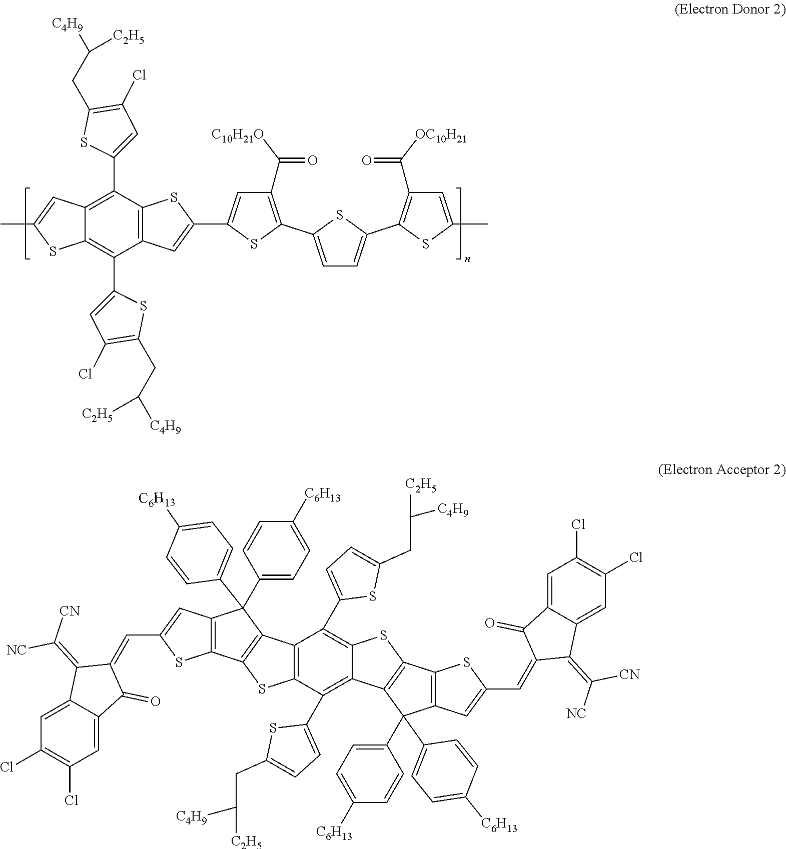

Electron Acceptor 3 is (2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(3-oxo-2,3-dihydro-1H-indene-2,1-diylidene))dimalononitrile). The following is the structure of Electron Acceptor3.

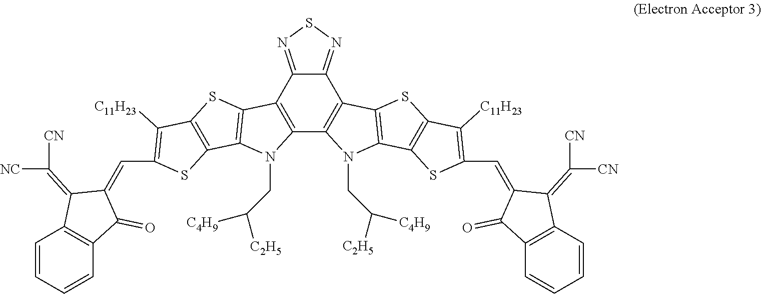

The material of the hole-transporting layer (50) is molybdenum trioxide (MoO₃).

The material of the second electrode (60) may be alkali metals or alkaline earth metal, such as lithium, magnesium or calcium. In addition, the material of the second electrode (60) may be tin, silver or aluminum. Preferably, the material of the second electrode (60) is silver.

Production of an organic photovoltaic device (OPV): the inverted organic solar cells of Examples 5 to 11 and Comparative Examples 1 to 3 are prepared in the following manner, and the results are shown in Table 1 described later.

Before manufacturing the organic photovoltaic device, the patterned ITO glass substrate (12 Ω/□) is sequentially washed in an ultrasonic oscillating tank with detergent, deionized water, acetone and isopropanol for 15 minutes, respectively. After being cleaned by ultrasonic oscillation, the ITO glass substrate is placed in in an UV-ozone cleaner for the surface treatment for 20 minutes. The glass substrate is the aforementioned substrate (10) and the ITO is the aforementioned first electrode (20).

ZnO (zinc oxide) is deposited on the ITO glass substrate via vapor deposition and used for the electrode interface layer (30) in Comparative Examples 1 to 3. In addition, each of Polymer 1 to Polymer 4 is prepared into an aqueous solution of the polyethyleneimine having the zwitterionic group suitable for spin coating, and then each aqueous solution is spin-coated on the ITO glass substrate. Each aqueous solution on the ITO glass substrate is baked in air at 100° C. for 5 minutes to form the electrode interface layer (30) (Examples 5 to 11). Wherein, the pH value of the aqueous solution of the polyethyleneimine having the zwitterionic group is adjusted with acetic acid, sulfuric acid, hydrochloric acid, phosphoric acid, perchloric acid, carbonic acid, nitric acid, p-toluenesulfonic acid or trifluoroacetic acid. The pH value of the aqueous solution of the polyethyleneimine having the zwitterionic group is between 5-8.

Next, the electron donor and non-fullerene material electron acceptor (non-fullerene acceptor, NFA) according to the weight ratio listed in Table 1 are dissolved in chlorobenzene which is used as a solvent to form a solution, and then the solution is spin-coated on the electrode interface layer (30) in Comparative Examples 1 to 3 and Examples 5 to 11, and then the solution on the electrode interface layer (30) is heated to remove chlorobenzene to form the active layer (40) in Comparative Examples 1 to 3 and Examples 5 to 11.

Then, molybdenum trioxide is thermally deposited on the active layer (40) in a vacuum chamber at 1.0×10⁻⁶ torr to form the hole-transporting layer (50) (thickness: 4 nm) in Comparative Examples 1 to 3 and Examples 5 to 11.

Finally, silver is thermally deposited on the hole-transporting layer (50) in a vacuum chamber to form the second electrode (60) (thickness: 100 nm) in Comparative Examples 1 to 3 and Examples 5 to 11.

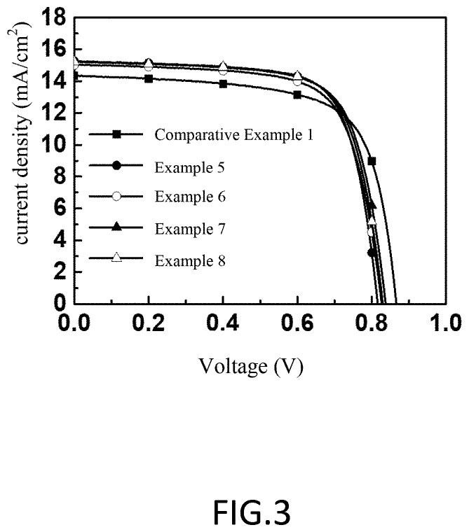

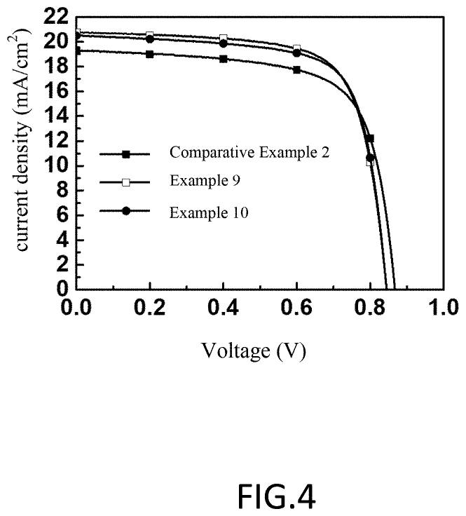

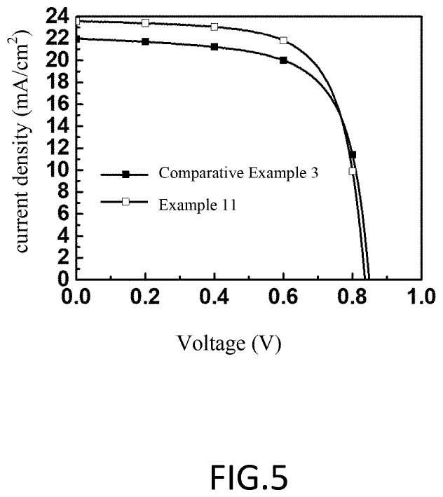

The measuring area of the organic photovoltaic device is defined as 0.04 cm² via a metal mask. The electrical property of the device is measured by using a power supply (Keithley 2400) (controlled by Lab-View program) under an AM1.5G simulated sunlight (SAN-EI XES-40S3) with an illumination of 100 mW/cm², and then the result is recorded by a computer program to obtain the voltage-current density graph as shown in FIG. 3, FIG. 4 and FIG. 5.

TABLE 1
Characteristics of organic photovoltaic devices

| | Polymer Or | Electron Donor And | | | | |
|---|---|---|---|---|---|---|
| | Zinc Oxide Used | Electron Acceptor | | | | |
| | For Electrode | Used For Active Layer | V_{oc} | Jₛₑ | FF | PCE |
| Project | Interface Layer | And Weight Ratio | (V) | (mA/cm⁻²) | (%) | (%) |
| Comparative example 1 | ZnO | Electron Donor | 0.87 | 14.35 | 69 | 8.6 |
| Example 5 | Polymer 1 | 1:Electron Acceptor | 0.82 | 15.27 | 73 | 9.0 |
| Example 6 | Polymer 2 | 1 = 1:1 | 0.83 | 15.02 | 71 | 8.8 |
| Example 7 | Polymer 3 | | 0.84 | 15.20 | 71 | 9.1 |
| Example 8 | Polymer 4 | | 0.83 | 15.22 | 72 | 9.1 |
| Comparative Example 2 | ZnO | Electron Donor | 0.87 | 19.30 | 70 | 11.6 |
| Example 9 | Polymer 1 | 2:Electron Acceptor | 0.85 | 20.76 | 72 | 12.6 |
| Example 10 | Polymer 4 | 2 = 1:1 | 0.84 | 20.49 | 72 | 12.5 |
| Comparative Example 3 | ZnO | Electron Donor | 0.85 | 21.95 | 68 | 12.7 |
| Example 11 | Polymer 4 | 1:Electron Acceptor | 0.84 | 23.57 | 69 | 13.7 |
| | | 3 = 1:1.5 | | | | |

In Table 1, Voc represents the open voltage, Jsc represents the short-circuit current, FF represents the fill factor and PCE represents the energy conversion efficiency. Referring to FIG. 3, FIG. 4, and FIG. 5, the open voltage and short-circuit current are the intercept of the voltage-current density curve on the X-axis and Y-axis. In addition, the fill factor is the value obtained by dividing the area that can be drawn in the curve by the product of the short-circuit current and open voltage. When the three values of the open voltage, short-circuit current and fill factor are divided by the irradiated light, the energy conversion efficiency can be obtained, and the higher value of the energy conversion efficiency is better. According to the results in Table 1, compared to the organic photovoltaic devices of Comparative Examples 1 to 3 (using ZnO as the electrode interface layer), the organic photovoltaic devices of Examples 5 to 11 (using Polymer 1-4 of polyethyleneimine having zwitterionic group as the electrode interface layer) have higher short-circuit currents (Jsc), fill factors (FF) and energy conversion efficiencies (PCE). Therefore, from the foregoing result, it can be seen that when the polyethyleneimine having the zwitterionic group of the present invention is used as the electrode interface layer material, and the energy conversion efficiency (PCE) of the organic photovoltaic device can be effectively improved.

Although the present invention has been disclosed and described through specific embodiments, it is obvious to one person skilled in the art that the present invention is applicable to various other embodiments. Therefore, the scope of the present invention shall be defined by the scope of the claim attached to this application.

What is claimed is:

1. An electrode interface layer material, comprising polyethyleneimine having a zwitterionic group, the zwitterionic group having a cationic group and an anionic group; wherein the cationic group is selected from the group consisting of a secondary ammonium cation group, a tertiary ammonium cation group and a quaternary ammonium cation group.

2. The electrode interface layer material of claim 1, wherein the anionic group of the zwitterionic group is selected from the group consisting of an oxyanion group, a carboxylate anion group, a phosphate anion group and a sulfonate anion group.

3. The electrode interface layer material of claim 2, wherein the polyethyleneimine having the zwitterionic group is formed by a reaction of polyethyleneimine and a modifier, wherein the modifier is epoxide, acid anhydride, lactone, sultone or phosphate.

4. The electrode interface layer material of claim 2, wherein the polyethyleneimine having the zwitterionic group is formed by a crosslinking reaction of polyethyleneimine and a compound having at least two crosslinking groups.

5. The electrode interface layer material of claim 4, wherein the crosslinking group is an ethylene oxide group, an acid anhydride group or an isocyanate group.

6. The electrode interface layer material of claim 2, wherein the polyethyleneimine having the zwitterionic group is formed by the following steps: undergoing a crosslinking reaction of polyethyleneimine and a compound having at least two crosslinking groups; and reacting with a modifier, wherein the modifier is lactone, sultone or phosphate.

7. The electrode interface layer material of claim 2, wherein the anionic group of the zwitterionic group is the oxyanion group, and polyethyleneimine is crosslinked with epoxide which is used as a cross-linker, wherein the epoxide is glycerol diglycidyl ether, bisphenol A diglycidyl ether, 1,4-butanediol diglycidyl ether, poly(propylene glycol)diglycidyl ether, polyoxypropylene diglycidyl ether or trimethylolpropane triglycidyl ether.

8. The electrode interface layer material of claim 2, wherein the anionic group of the zwitterionic group is the carboxylate anion group, polyethyleneimine is crosslinked with acid anhydride which is used as a cross-linker, wherein the acid anhydride is acetic anhydride or maleic anhydride.

9. The electrode interface layer material of claim 2, wherein the anionic group of the zwitterionic group is the sulfonate anion group, polyethyleneimine is crosslinked with sultone which is used as a cross-linker, wherein the sultone is 1,3-propanesultone or 1,4-butanesultone.

10. The electrode interface layer material of claim 1, further comprising a solvent for the polyethyleneimine having the zwitterionic group, wherein the solvent is alcohol.

11. The electrode interface layer material of claim 1, further comprising a solvent for the polyethyleneimine having the zwitterionic group, wherein the solvent is a mixture of alcohol and water.

12. The electrode interface layer material of claim 1, wherein the polyethyleneimine having the zwitterionic group is dissolved as an aqueous solution, wherein the pH value of the aqueous solution is adjusted with acetic acid, sulfuric acid, hydrochloric acid, phosphoric acid, perchloric acid, carbonic acid, nitric acid, p-toluenesulfonic acid or trifluoroacetic acid.

13. The electrode interface layer material of claim 1, wherein the polyethyleneimine having the zwitterionic group is dissolved as an aqueous solution, wherein the pH value of the aqueous solution of the polyethyleneimine having the zwitterionic group is between 5-8.

14. An electrode interface layer of an inverted organic solar cell including the electrode interface layer material of claim 1, wherein a surface of the electrode interface layer includes an active layer containing a non-fullerene material, or the surface of the electrode interface layer is contacted with the non-fullerene material.

15. An organic photovoltaic device, including the electrode interface layer material of claim 1.

16. The organic photovoltaic device of claim 15, wherein the organic photovoltaic device includes: a first electrode; an electrode interface layer deposited on the first electrode; an active layer deposited on the electrode interface layer; a hole-transporting layer deposited on the active layer; and a second electrode deposited on the hole-transporting layer, wherein the electrode interface layer includes the electrode interface layer material.

17. The organic photovoltaic device of claim 15, wherein the organic photovoltaic device includes: a first electrode; a hole-transporting layer deposited on the first electrode; an active layer deposited on the hole-transporting layer; an electrode interface layer deposited on the active layer; and a second electrode deposited on the electrode interface layer, wherein the electrode interface layer includes the electrode interface layer material.

18. A zwitterionic polymer, represented by the following formula (1): 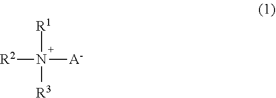
wherein,
N is nitrogen and N⁺ is a cationic group;
R¹, R² and R³ are independently H or a polyethyleneimine group, and at least one of R¹, R² and R³ is the polyethyleneimine group; and
A⁻ is an anionic group, and A⁻ is a substituted alkyl group having 1 to 4 carbons in which one H in the chain is substituted with an oxyanion group, a carboxylate anion group, a phosphate anion group or a sulfonate anion group.

19. An electrode interface layer of an inverted organic solar cell including the zwitterionic polymer of claim 18, wherein a surface of the electrode interface layer includes an active layer containing a non-fullerene material, or the surface of the electrode interface layer is contacted with the non-fullerene material.

20. An organic photovoltaic device, including the zwitterionic polymer of claim 18.

21. The organic photovoltaic device of claim 20, wherein the organic photovoltaic device includes: a first electrode; an electrode interface layer deposited on the first electrode; an active layer deposited on the electrode interface layer; a hole-transporting layer deposited on the active layer; and a second electrode deposited on the hole-transporting layer, wherein the electrode interface layer includes the zwitterionic polymer.

22. The organic photovoltaic device of claim 20, wherein the organic photovoltaic device includes: a first electrode; a hole-transporting layer deposited on the first electrode; an active layer deposited on the hole-transporting layer; an electrode interface layer deposited on the active layer; and a second electrode deposited on the electrode interface layer, wherein the electrode interface layer includes the zwitterionic polymer.
